(19) United States
(12) Patent Application Publication
(10) Pub. No.: US 2008/0305604 A1
(43) Pub. Date: Dec. 11, 2008

(54) DEEP TRENCH AND FABRICATING METHOD THEREOF, TRENCH CAPACITOR AND FABRICATING METHOD THEREOF

(75) Inventor: Shian-Jyh Lin, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: NANYA TECHNOLOGY CORPORATION, Taoyuan (TW)

(21) Appl. No.: 11/943,586

(22) Filed: Nov. 21, 2007

(30) Foreign Application Priority Data
Jun. 8, 2007 (TW) 96120698

(51) Int. Cl. H01L 21/20

(52) U.S. Cl. 438/386; 257/E21.09

(57) ABSTRACT

A method of fabricating a deep trench is provided, by which a trench is formed in the substrate initially. Then, a block layer is formed on the substrate surface of the upper portion of the trench. After that, a pad oxide layer is formed on the substrate surface of the lower portion of the trench. Next, a plurality of hemispherical silicon grains is formed on the substrate and exposes a portion of the pad oxide layer. Then, by using the hemispherical silicon grains as a mask, a portion of the pad oxide layer is removed so as to form a patterned pad oxide layer. Continually, the hemispherical silicon grains and the substrate exposed by the patterned pad oxide layer are removed. Finally, the patterned pad oxide layer is removed.

### CROSS-REFERENCE TO RELATED APPLICATION

This application claims the priority benefit of Taiwan application serial no. 96120698, filed on Jun. 8, 2007. All disclosure of the Taiwan application is incorporated herein by reference.

### BACKGROUND OF THE INVENTION

1. Field of the Invention

The present invention relates to a fabricating method of a capacitor, and more particularly, to a fabricating method of a trench capacitor.

2. Description of Related Art

With continually miniaturized components, sizes of electrical components are increasingly decreased. As for memory components having capacitors, the trend of size reducing means the available space used for fabricating capacitors become smaller and smaller. Hence, how to make capacitors with sufficient capacity becomes one of the most important issues to the recent semiconductor fabrication technology.

Generally, there are a lot of methods for increasing the charge storage capacity of capacitors, such as decreasing the thickness of the dielectric layer between electrodes or increasing the area of capacitors so as to increase the number of charges stored in the capacitors. The design of a trench capacitor is a method for fabricating capacitors by using the spaces in the substrate to increase the area of the capacitors.

To achieve high capacitance value, the method commonly adopted by the industry is to increase the surface area of the lower electrodes of the capacitors. For example, one of the commonly adopted methods is by forming a hemispherical silicon grain (HSG) layer on the lower electrodes of the capacitors.

FIG. 1 is a cross-sectional view of a conventional trench capacitor. The trench capacitor is consisted of a substrate 100, a doped region 102, a hemispherical silicon grain (HSG) layer 104, a capacitor dielectric layer 106, a first conductive layer 108, a collar oxide layer 110 and a second conductive layer 112. Herein, the substrate 100 has a trench 114. The doped region 102 is disposed in the substrate 100 of the lower portion of the trench 114. The HSG layer 104 is disposed on the doped region 102. The first conductive layer 108 is surrounded by the HSG layer 104 of the lower portion of the trench 114. The capacitor dielectric layer 106 is disposed between the first conductive layer 108 and the HSG layer 104. The collar oxide layer 110 is disposed on the upper portion of the trench 114. The second conductive layer 112 is disposed on top of the first conductive layer 108 to engage with the first conductive layer 108 and be surrounded by the collar oxide layer 110. As shown in FIG. 1, the HSG layer 104 in a hemispherical undulating shape protruding inwards toward the first conductive layer 108 can increase the surface area of the doped region 102 to further increase the capacitance value of the entire capacitor. However, when the fabricating technique of components enters into a sub-micron process, the technique of the HSG layer is no longer suitable for processes having a line width smaller than 100 nm. This is because the size of grains of the HSG layer becomes relatively large when the line width is smaller than 100 nm, which is unfavorable for the follow-up processes such as the formation of the capacitor dielectric layer 106 and the first conductive layer 108. Therefore, how to keep capacitors having good capacitance value under the trend toward smaller line width is an important issue that the industry has to face to.

### SUMMARY OF THE INVENTION

In view of the foregoing, one aspect of the present invention is to provide a fabricating method of a deep trench, by which a capacitor area can be increased so as to increase the capacitance value of capacitors.

Another aspect of the present invention is to provide a fabricating method of a trench capacitor, by which the area of a doped region can be increased so that the capacitor area can be increased to further improve the storage ability of charges.

Yet another aspect of the present invention is to provide a trench capacitor having a structure in which a large contacting area of the capacitor is provided so as to allow the capacitor to have a good capacitance value.

Still another aspect of the present invention furthermore is to provide a deep trench structure having a large surface area on the lower portion of the trench.

The present invention provides a fabricating method of a deep trench. Initially, a trench is formed in a substrate. Then, a block layer is formed on the substrate surface of the upper portion of the trench. Thereafter, a pad oxide layer is formed on the substrate surface of the lower portion of the trench. Next, a plurality of hemispherical silicon grains is formed on the substrate and exposes a portion of the pad oxide layer. Then, by using the hemispherical silicon grains as a mask, the portion of the pad oxide layer is removed so as to form a patterned pad oxide layer. Continually, the hemispherical silicon grains and a portion of the substrate exposed by the patterned pad oxide layer are removed. Finally, the patterned pad oxide layer is removed.

According to the fabricating method of the deep trench described in an embodiment of the present invention, a method for forming the hemispherical silicon grains is performing a chemical vapor deposition process, for example.

According to the fabricating method of the deep trench described in an embodiment of the present invention, a method for removing the pad oxide layer is performing a wet etching process, for example.

According to the fabricating method of the deep trench described in an embodiment of the present invention, a method for forming the pad oxide layer is performing a thermal oxidation process, for example.

According to the fabricating method of the deep trench described in an embodiment of the present invention, a method for removing the hemispherical silicon grains and the portion of the substrate exposed by the patterned pad oxide layer is performing the wet etching process, for example.

According to the fabricating method of the deep trench described in an embodiment of the present invention, the material of the block layer is aluminum oxide (Al₂O₃), for example.

According to the fabricating method of the deep trench described in an embodiment of the present invention, a method for forming the block layer is performing an atomic layer deposition process, for example.

According to the fabricating method of the deep trench described in an embodiment of the present invention, a method for forming the block layer is started with forming a sacrificial oxide layer on the substrate surface of the trench, for example. Then, a photoresist layer is formed on the substrate of the lower portion of the trench. Next, a portion of the sacrificial oxide layer is removed by using the photoresist layer as the mask. After that, the photoresist layer is removed. Then, a silicon nitride layer is formed on the substrate surface of the upper portion of the trench. Finally, the sacrificial oxide layer is removed.

According to the fabricating method of the deep trench described in an embodiment of the present invention, a method for forming the trench is started with forming a patterned mask layer on the substrate, for example. Thereafter, by using the patterned mask layer as the mask, an etching process is performed to form the trench in the substrate.

The present invention provides a fabricating method of a trench capacitor. Initially, a trench is formed in a substrate. Then, a block layer is formed on the substrate surface of the upper portion of the trench. After that, a pad oxide layer is formed on the substrate surface of the lower portion of the trench. Next, a plurality of hemispherical silicon grains is formed on the substrate, which exposes a portion of the pad oxide layer. Then, by using the hemispherical silicon grains as a mask, the portion of the pad oxide layer is removed so as to form a patterned pad oxide layer. Continually, the hemispherical silicon grains and the substrate exposed by the patterned pad oxide layer are removed. Next, the patterned pad oxide layer is removed. After that, a doped region is formed in the substrate of the lower portion of the trench. Then, a capacitor dielectric layer is formed on the substrate of the lower portion of the trench. Next, a first conductive layer is formed on the capacitor dielectric layer. Sequentially, the block layer is removed. Finally, a collar oxide layer is formed to cover the substrate surface of the upper portion of the trench.

According to the fabricating method of the trench capacitor described in an embodiment of the present invention, a method for forming the hemispherical silicon grains is performing a chemical vapor deposition process, for example.

According to the fabricating method of the trench capacitor described in an embodiment of the present invention, a method for removing the pad oxide layer is performing a wet etching process, for example.

According to the fabricating method of the trench capacitor described in an embodiment of the present invention, a method for forming the pad oxide layer is performing a thermal oxidation process, for example.

According to the fabricating method of the trench capacitor described in an embodiment of the present invention, a method for removing the hemispherical silicon grains and the substrate exposed by the patterned pad oxide layer is performing a wet etching process, for example.

According to the fabricating method of the trench capacitor described in an embodiment of the present invention, the material of the block layer is aluminum oxide (Al₂O₃), for example.

According to the fabricating method of the trench capacitor described in an embodiment of the present invention, a method for forming the block layer is performing an atomic layer deposition process, for example.

According to the fabricating method of the trench capacitor described in an embodiment of the present invention, a method for forming the block layer is started with forming a sacrificial oxide layer on the substrate surface of the trench, for example. Then, a photoresist layer is formed on the substrate of the lower portion of the trench. Next, by using the photoresist layer as the mask, the sacrificial oxide layer is removed. After that, the photoresist layer is removed. Then, a silicon nitride layer is formed on the substrate surface of the upper portion of the trench. Finally, the sacrificial oxide layer is removed.

According to the fabricating method of the trench capacitor described in an embodiment of the present invention, a method for forming the doped region is performing an ion implanting process or a thermal diffusion process, for example.

According to the fabricating method of the trench capacitor described in an embodiment of the present invention, the material of the capacitor dielectric layer includes silicon oxide/silicon nitride/silicon oxide, for example.

According to the fabricating method of the trench capacitor described in an embodiment of the present invention, a method for forming the capacitor dielectric layer is a performing a chemical vapor deposition process, for example.

According to the fabricating method of the trench capacitor described in an embodiment of the present invention, a method for forming the first conductive layer is started with forming a conductive material layer on the substrate, which fills in the trench. Then, an etching back process is performed to remove the conductive material layer outside of the trench and in the upper portion of the trench.

According to the fabricating method of the trench capacitor described in an embodiment of the present invention, the material of the first conductive layer is doped polysilicon, for example.

According to the fabricating method of the trench capacitor described in an embodiment of the present invention, a method for forming the collar oxide layer is started with forming a collar oxide material layer on the side wall of the trench and on the first conductive layer, for example. Then, the collar oxide material layer on the first conductive layer is removed.

According to the fabricating method of the trench capacitor described in an embodiment of the present invention, the method further includes forming a second conductive layer to fill in the trench after the collar oxide layer is formed.

According to the fabricating method of the trench capacitor described in an embodiment of the present invention, the material of the second conductive layer is doped polysilicon, for example.

According to the fabricating method of the trench capacitor described in an embodiment of the present invention, a method for forming the trench is started with forming a patterned mask layer on the substrate, for example. Thereafter, using the patterned mask layer as the mask, an etching process is performed to form the trench in the substrate.

The present invention provides a trench capacitor. The trench capacitor includes a substrate, a doped region, a first conductive layer, a capacitor dielectric layer, a collar oxide layer and a second conductive layer. The substrate has a trench, wherein the substrate surface in the lower portion of the trench presents an undulating shape extending away from a center of the trench. The doped region is disposed in the substrate of the lower portion of the trench. The first conductive layer is provided to fill in the lower portion of the trench. The capacitor dielectric layer is disposed between the first conductive layer and the doped region. The collar oxide layer is disposed on the inner surface of the upper portion of the trench. The second conductive layer is provided to fill in the upper portion of the trench and above the first conductive layer.

The present invention provides a deep trench structure, which includes a substrate and a trench. The trench is disposed in the substrate and the substrate surface of the lower portion of the trench presents an undulating shape extending away from the center of the trench.

According to the deep trench structure described in an embodiment of the present invention, the substrate is a silicon substrate.

Since the fabricating method of the trench capacitor of the present invention can produce the substrate surface presenting an undulating shape extending away from the center of the trench, the capacitor area can be increased by the undulating surface so that the capacitor can have good charge storage ability.

In order to make the aforementioned and other objects, features and advantages of the present invention comprehensible, several embodiments accompanied with figures are described in the following detail.

### BRIEF DESCRIPTION OF THE DRAWINGS

FIG. 1 is a cross-sectional view illustrating a conventional trench capacitor.

FIGS. 2A-2H are cross-sectional views illustrating the steps for fabricating a trench capacitor according to an embodiment of the present invention.

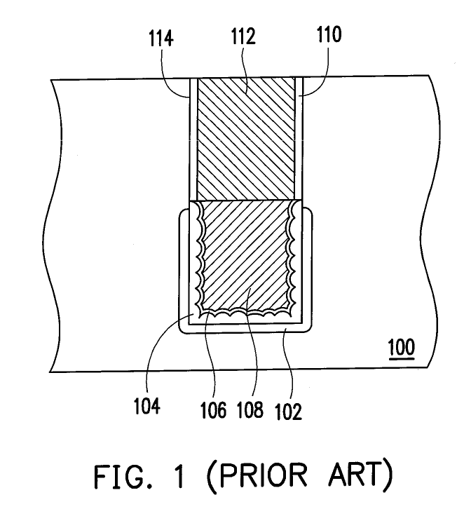

### DESCRIPTION OF EMBODIMENTS

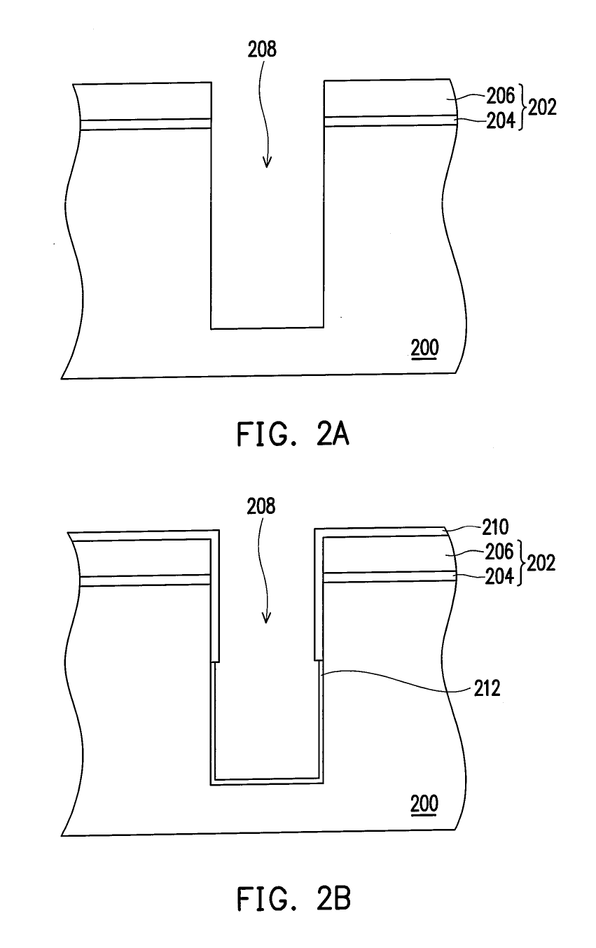

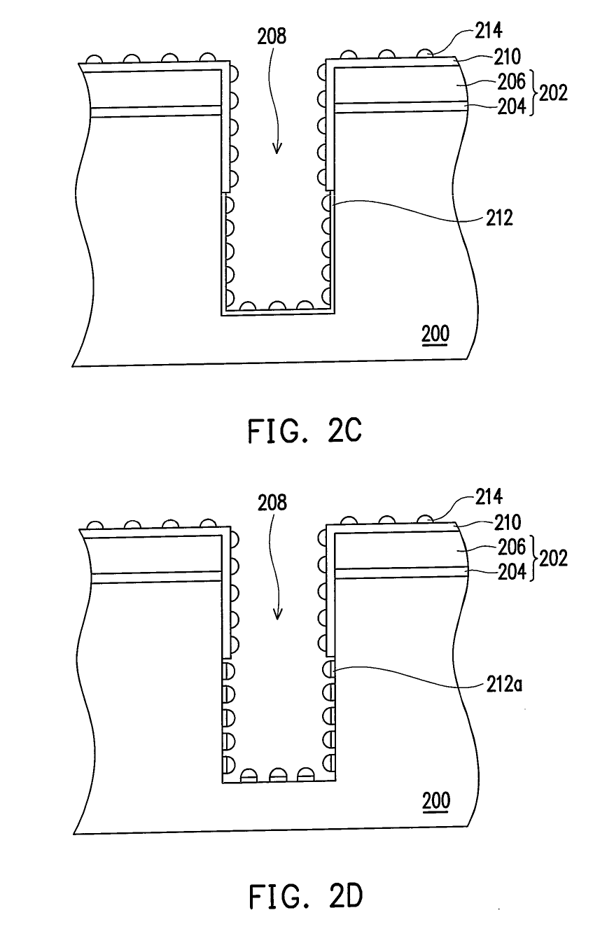

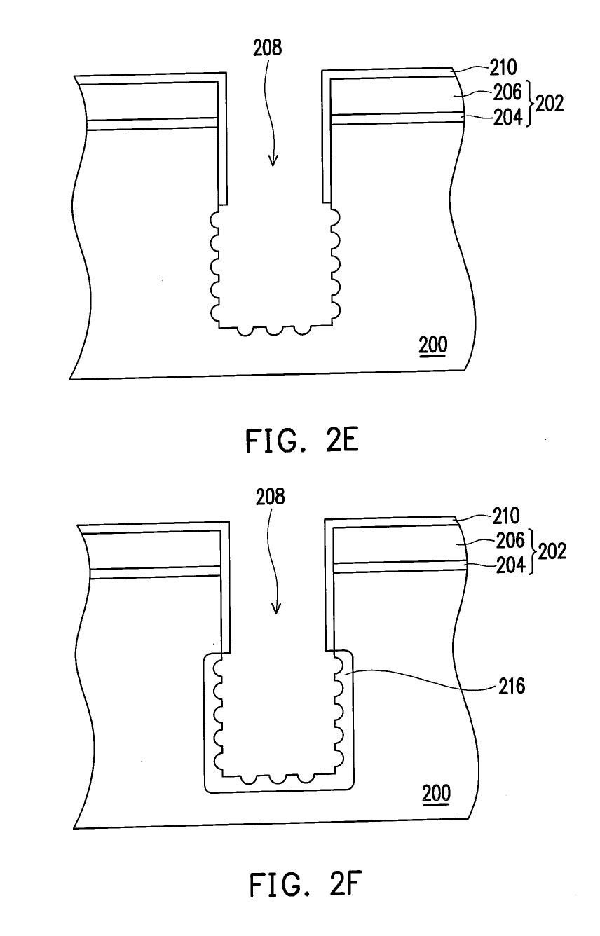

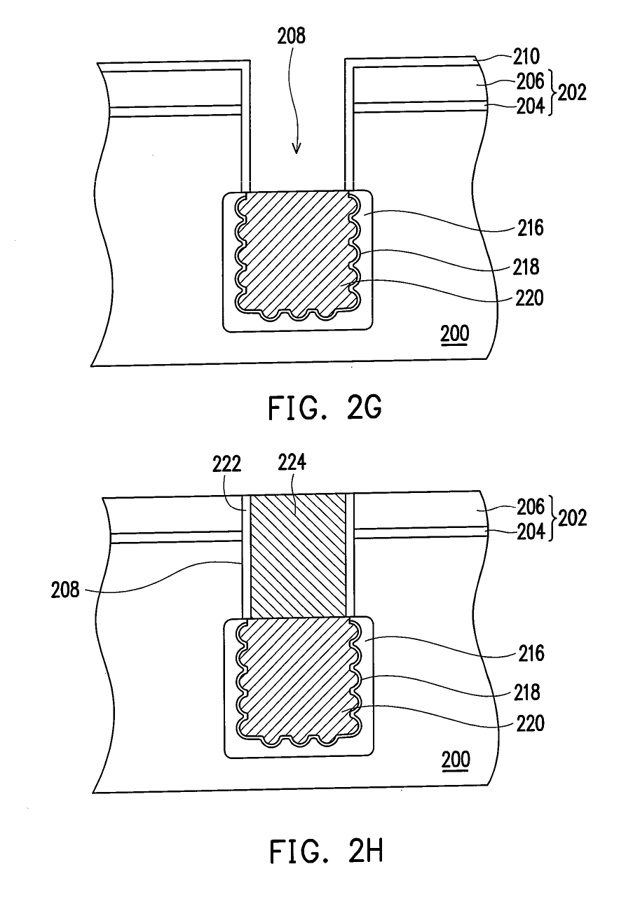

FIGS. 2A-2H are cross-sectional views illustrating the steps for fabricating a trench capacitor according to an embodiment of the present invention. Initially, referring to FIG. 2A, a substrate 200 is provided, wherein the substrate 200 is a silicon substrate or other proper semiconductor substrate, for example.

Next, a patterned mask layer 202 is formed on the substrate 200. The patterned mask layer 202 is consisted of a pad oxide layer 204 and a silicon nitride layer 206, for example. For example, a method for forming the patterned mask layer 202 is started by forming a silicon oxide layer used as the pad oxide layer 204 on the substrate 200 via a thermal oxidation process. Next, a chemical vapor deposition process is performed to form a silicon nitride layer 206 on the pad oxide layer 204. Then, a photolithographic process and an etching process are performed to form the patterned mask layer 202 on the substrate 200.

After that, the substrate 200 is etched by using the patterned mask layer 202 as an etching mask to form a trench 208 in the substrate 200.

Next, referring to FIG. 2B, a block layer 210 is formed on the patterned mask layer 202 and an inner surface of an upper portion of the trench 208. The material of the block layer 210 is aluminum oxide (Al₂O₃), for example, and the forming method thereof is by performing an atomic layer deposition (ALD) process, for example.

Continually, a pad oxide layer 212 is formed on an inner surface of a lower portion the trench 208. The method for forming the pad oxide layer 212 is performing a thermal oxidation process, for example.

Alternatively, the method for forming the block layer 210 may be started with forming the pad oxide layer 212 as a sacrificial oxide layer on the outer surface of the patterned mask layer 202 and the inner surface of the trench 208, for example. Next, a photoresist layer (not shown) is formed on a lower portion of the inner surface of the trench 208. Then, the pad oxide layer 212 on an upper portion of the trench 208 is removed by using the photoresist layer as a mask. After that, the photoresist layer is removed. Then, a silicon nitride layer is formed on the surface of the upper portion of the trench 208, wherein the silicon nitride layer is used as the block layer 210. The method for forming the silicon nitride layer is a performing thermal nitrification process, for example.

Next, referring to FIG. 2C, a plurality of hemispherical silicon grains 214 is equally formed on the substrate 200, wherein the hemispherical silicon grains 214 expose a portion of the pad oxide layer 212. The method for forming the hemispherical silicon grains 214 is, for example, performing a chemical vapor deposition process.

With reference to FIG. 2D, a portion of the pad oxide layer 212 which is not covered by the hemispherical silicon grains 214 is removed by using the hemispherical silicon grains 214 as the etching mask to form the patterned pad oxide layer 212a. The method for removing the portion of the pad oxide layer 212 which is not covered by the hemispherical silicon grains 214 is performing a wet etching process on the pad oxide layer 212 by using diluted hydrofluoric acid solution (DHF) or other proper etchants, for example.

After that, referring to FIG. 2E, the hemispherical silicon grains 214 and the portion of the substrate 200 exposed by the patterned pad oxide layer 212a are removed. The method for removing the hemispherical silicon grains 214 and the portion of the substrate 200 exposed by the patterned pad oxide layer 212a is performing a wet etching process by using tetramethyl ammonium hydroxide (NH₄OH) or other proper etchants. In the meantime, the inner surface of the lower portion of the trench 208 presents an undulating shape, which indicates that the undulating structure extends away from the trench 208. The undulated lower portion of the trench 208 can allow the sequentially formed doped region to have a large surface area. Therefore, the capacitor completed by following-up fabricating processes can have good capacitance value.

Then, the patterned pad oxide layer 212a is removed. The method for removing the patterned pad oxide layer 212 is performing an etching process on the pad oxide layer 212 by using diluted hydrofluoric acid solution (DHF) or other proper etchants, for example.

After that, referring to FIG. 2F, a doped region 216 is formed on the lower portion of the trench 208. The method for forming the doped region 216 is started with forming a doped oxide layer (not shown) on the inner surface of the lower portion of the trench 208, for example. The method for forming the doped oxide layer is performing chemical vapor deposition process, for example, and an ion doped in such oxide layer is arsenic ion, for example. Then, a thermal process is performed so that the doped ion in the doped oxide layer can be diffused into the substrate 200 so as to form the doped region 216 surrounding the lower portion of the trench 208. Moreover, an ion implanting process or a gas phase diffusion process can also be performed to form the doped region 216 surrounding the lower portion of the trench 208.

Then, referring to FIG. 2G, a capacitor dielectric layer 218 is formed on the inner surface the lower portion of the trench 208. The material of the capacitor dielectric layer 218 includes silicon oxide/silicon nitride/silicon oxide and the method for forming the same is performing a chemical vapor deposition process, for example. In addition, the material of the capacitor dielectric layer 218 can alternatively be a high-k material, and the method forming the capacitor dielectric layer 218 is performing an atomic layer deposition process, for example.

Next, a first conductive layer 220 is provided to fill in the lower portion of the trench 208 to be enclosed by the capacitor dielectric layer 218. The method for forming the first conductive layer 220 is started with forming a doped polysilicon layer (not shown) on the substrate 200 by performing the chemical vapor deposition process inside the lower portion of the trench 208. Then, an etching back process is performed to remove the doped polysilicon layer outside the lower portion of the trench 208.

Next, the capacitor dielectric layer 218 which is not covered by the first conductive layer 220 is removed.

Eventually, referring to FIG. 2H, the block layer 210 is removed. The method for removing the block layer 210 is performing an etching process, for example.

Next, a collar oxide layer 222 is formed on an inner surface of the upper portion of the trench 208. The method for forming the collar oxide layer 222 is started with forming a collar oxide material layer (not shown) on the inner side wall of the trench 208, on top of the first conductive layer 220 and on the surface of the mask layer 202, for example. The method for forming the collar oxide material layer is, for example, performing a CVD process, and the reacting gas is ozone (O₃) or tetraethyl orthosilicate (TEOS), for example. Then, an anisotropic etching process is performed to remove the collar oxide material layer on top of the first conductive layer 220 and on top of the surface of the mask layer 202 so that the collar oxide material layer disposed on the inner side wall of the trench 208 is sustained, and hence, the collar oxide layer 222 is formed.

Thereafter, a second conductive layer 224 is provided to fill in the top portion of the trench 208. The method for filling the second conductive layer 224 is started with forming a doped polysilicon layer (not shown) inside the trench 208 of the substrate 200 by performing the chemical vapor deposition process and hence, the trench 208 is filled. After that, a chemical mechanic polishing process is performed to remove excessive polysilicon layer outside of the trench 208, wherein, the second conductive layer 224 is used for connecting with a drain of a transistor (not shown). So far, the following-up processes for accomplishing the trench capacitor is well known to those skilled in this art, which will not be described herein.

In the fabricating method of the trench capacitor of the present invention, a portion of the substrate 200 of the lower portion of the trench 208 is removed so as to present an undulating shape to increase the capacitor area, which is different from the conventional cases where the hemispherical silicon grains are directly formed on the substrate 200 of the lower portion of the trench 208. Therefore, even though requirements for the scale of the line width becomes increasingly narrow, e.g. smaller than 100 nm, the trench capacitor having good capacitance value can be produced based on the fabricating method of present invention.

Following the above, a trench capacitor structure is described hereinafter. Referring to FIG. 2H, a trench capacitor structure of the present invention includes the substrate 200, the doped region 216, the first conductive layer 220, the capacitor dielectric layer 218, the collar oxide layer 222 and the second conductive layer 224. Herein, the trench 208 is disposed in the substrate 200, and the inner surface of the lower portion of the trench 208 presents an undulating shape extending away from a center of the trench 208. The doped region 216 is disposed in the inner surface of the lower portion of the trench 208. The first conductive layer 220 is provided to fill in the lower portion of the trench 208 and the material of the first conductive layer 220 is doped polysilicon, for example. The capacitor dielectric layer 218 is disposed between the first conductive layer 220 and the doped region 216, and the material of the capacitor dielectric layer 218 includes silicon oxide/silicon nitride/silicon oxide or a high-k material, for example. The collar oxide layer 222 is disposed on the inner surface of the upper portion of the trench 208. The second conductive layer 224 is provided to be on top of the first conductive layer 220 and to fill in the top portion of the trench 208, and the material of the second conductive layer 224 is doped polysilicon, for example.

The doped region 216 of the trench capacitor of the present invention has an undulating surface. To describe in more details, the undulating surface of the doped region 216 is formed by removing part of the substrate 200 of the lower portion of the trench 208, and therefore a concave profile of the inner surface of the substrate 200 of the lower portion of the trench 208 is formed. The concave profile of the doped region 216 is different from the protruding profile on the substrate surface of the lower portion of the trench of the conventional technology formed by using the hemispherical silicon layer technique. Therefore, the trench capacitor of the present invention has a lager capacitor area when compared with the conventional technology so as to have better capacitance value and avoid defects of the conventional technology in which the fabrication is difficult to perform especially when the line width is decreased.

In view of the foregoing, the fabricating method of the trench capacitor of the present invention can effectively increase the capacitor area, and even if the requirements for the line width becomes increasingly narrow, the trench capacitor having good charge storage ability can still be produced based on the fabricating method of present invention.

Although the present invention has been described with reference to the above embodiments, it will be apparent to one of the ordinary skill in the art that modifications to the described embodiment may be made without departing from the spirit of the present invention. Accordingly, the scope of the present invention will be defined by the attached claims not by the above detailed description.

What is claimed is:

1. A trench fabricating method consisting essentially of the steps of:
forming a trench in a substrate to allow the trench to have a lower portion and an upper portion;
forming multiple undulating concaves in an inner surface of the lower portion of the trench of the substrate, wherein the undulating concaves extend away from a center of the trench.

2. The method as claimed in claim 1 further comprising:
a step of forming an oxidation layer on the inner surface of the lower portion of the trench and a bottom surface of the trench; and
a step of forming a nitrification layer on an inner surface of the upper portion of the trench and on an outer surface of the substrate.

3. The method as claimed in claim 2, wherein the oxidation layer forming step is performed by proceeding a thermal oxidation process and the nitrification layer forming step is performed by proceeding a thermal nitrification process.

4. The method as claimed in claim 2, wherein multiple hemispherical silicon grains are formed on the oxidation layer on the inner surface of the lower portion of the trench as well as on the nitrification layer on the inner surface of the upper portion of the trench and on the outer surface of the substrate.

5. The method as claimed in claim 4 further comprising a step of removing the oxidation layer which is free of being covered by the hemispherical silicon grains.

6. The method as claimed in claim 5 further comprising a step of removing a portion of the inner surface of the lower portion of the trench which is free of the hemispherical silicon grains and the oxidation layer.

7. The method as claimed in claim 6 further comprising a step of removing the oxidation layer which is covered by the hemispheric silicon grains, wherein the hemispherical silicon grains are removed simultaneously during the step of removing the portion of the inner surface of the lower portion of the trench which is free of the hemispherical silicon grains and the oxidation layer.

8. The method as claimed in claim 1 further comprising:
a step of forming a oxidation layer on the inner surface of the lower portion of the trench and a bottom surface of the trench.

9. The method as claimed in claim 8, wherein the oxidation layer forming step is performed by proceeding a thermal oxidation process.

10. The method as claimed in claim 8, wherein multiple hemispherical silicon grains are formed on the oxidation layer on the inner surface of the lower portion of the trench and on the outer surface of the substrate.

11. The method as claimed in claim 10 further comprising a step of removing the oxidation layer which is free of being covered by the hemispherical silicon grains.

12. The method as claimed in claim 11 further comprising a step of removing a portion of the inner surface of the lower portion of the trench which is free of the hemispherical silicon grains and the oxidation layer.

13. The method as claimed in claim 12 further comprising a step of removing the oxidation layer which is covered by the hemispheric silicon grains, wherein the hemispherical silicon grains are removed simultaneously during the step of removing the portion of the inner surface of the lower portion of the trench which is free of the hemispherical silicon grains and the oxidation layer.
